(19) United States
(12) Patent Application Publication
(10) Pub. No.: US 2016/0087062 A1
(43) Pub. Date: Mar. 24, 2016

(54) SEMICONDUCTOR DEVICES AND METHODS FOR MANUFACTURING THE SAME

(71) Applicant: INSTITUTE OF MICROELECTRONICS, CHINESE ACADEMY OF SCIENCES, Beijing (CN)

(72) Inventors: Huaxiang YIN, Beijing (CN); Yongkui ZHANG, Beijing (CN); Zhiguo ZHAO, Beijing (CN); Zhiyong LU, Beijing (CN); Huilong ZHU, Beijing (CN)

(21) Appl. No.: 14/688,523

(22) Filed: Apr. 16, 2015

(30) Foreign Application Priority Data
Sep. 19, 2014 (CN) 201410484165.0

(51) Int. Cl. H01L 29/49; H01L 27/088; H01L 29/78; H01L 29/10; H01L 21/8234; H01L 29/66

(52) U.S. Cl. CPC H01L 29/4916; H01L 21/823431; H01L 21/823412; H01L 21/823418; H01L 21/823437; H01L 21/823468; H01L 29/66545; H01L 29/66537; H01L 29/66492; H01L 29/7834; H01L 29/1083; H01L 27/0886

(57) ABSTRACT

A semiconductor device includes: a plurality of fin structures extending on a substrate along a first direction; a gate stack structure extending on the substrate along a second direction and across the plurality of fin structures, wherein the gate stack structure includes a gate conductive layer and a gate insulating layer, and the gate conductive layer is formed by a doped poly-semiconductor; trench regions in the plurality of fin structures and beneath the gate stack structure; and source/drain regions on the plurality of fin structures and at both sides of the gate stack structure along the first direction.

This application claims priority to Chinese Patent Application No, 201410484165.0, filed on Sep. 19, 2014, entitled “SEMICONDUCTOR DEVICE AND METHOD FOR MANUFACTURING THE SAME”, which application is incorporated in its entirety by reference.

### FIELD

The present disclosure relates to semiconductor devices and methods of manufacturing the same, especially to a FinFET manufactured by a doped polysilicon gate-first process and a method of manufacturing the same.

### BACKGROUND

In the current sub-20 nm technology, three dimensional (3D) multi-gate devices (FinFETs or Tri-gates) are primary device structures, which improve controllability of the gate and suppress current leakage and short channel effects (SCE).

For example, as compared with a conventional single-gate bulk silicon or SOI MOSFET, a dual-gate SOI structure can suppress SCE and drain induced barrier lowering (DIBL) effects, have a lower junction capacitance to achieve a lightly-doped channel, and can adjust a threshold voltage by setting a work function of a metal gate to increase a driving current by a factor of about 2, thereby reducing the requirements on equivalent oxide thickness (EOT). As compared with dual-gate devices, tri-gate devices have gates surrounding a top surface and both opposite sides of the channel, thereby achieving a more powerful gate controllability. Further, all-around nanowire multi-gate devices are more advantageous.

In general, a method of manufacturing a FinFET structure comprises: etching in a bulk silicon or SOI substrate to form a plurality of parallel fins and trenches extending along a first direction; filling the trenches with an insulating material, and implementing etch-back to expose a part of the fins to form a shallow trench isolation (STI); depositing a thin (merely 1-5 nm, for example) dummy gate insulating layer (generally silicon oxide) on the top and sidewalls of the fins, and depositing a dummy gate layer (generally polysilicon or amorphous silicon) and a dummy gate cover layer (generally silicon nitride) on the dummy gate insulating layer; etching the dummy gate layer and the dummy gate insulating layer to form a dummy gate stack extending along a second direction, wherein the second direction is desirably perpendicular to the first direction; implementing a lightly doping implantation process at a tilt angle on the fins by taking the dummy gate stack as a mask to form a lightly doped drain (LDD) structure, in particular, a source/drain extension (SDE) structure to suppress DIBL effects; depositing and etching at both sides of the dummy gate stack along the first direction to form a gate spacer; epitaxially growing materials with similar lattice constants at both sides of the gate spacer to form source/drain regions with high stress (the gate spacer, the top of the dummy gate stack and the like cannot have a semiconductor material grown epitaxially thereon as they are made of an insulating dielectric material), wherein a material such as SiGe, SiC and the like with higher stress than silicon is desirably used to improve the carrier mobility; desirably, forming a contact etch stop layer (CESL) on the source/drain regions; depositing an interlayer dielectric (ILD) layer on the substrate; etching to remove the dummy gate stack and leave gate trenches in the ILD layer; and depositing, in the gate trenches, a gate insulating layer of a high-k (HK) material, a gate conductive layer of a metal/metal alloy/metal nitride (MG), and desirably a gate cover layer of a nitride material to protect the metal gate. Furthermore, source/drain contact holes are formed by using a mask to etch the ILD layer to expose the source/drain regions; and alternatively, metal silicide is formed in the source/drain contact holes to reduce source/drain contact resistance. A contact plug is formed by filling with metal/metal nitride, desirably a metal such as W, Ti and the like with a high filling rate. Due to the existence of the CESL and the gate spacer, the filled metal W and Ti will align with the source/drain regions automatically, to finally form the contact plug.

### SUMMARY

Although the metal gate and the gate stack structure formed by a high-k material as mentioned above can effectively improve gate controllability, for example, effectively suppress SCE and accurately adjust a threshold voltage, with the continuous shrinking of the characteristic size (a length of the trench regions, which typically is slightly larger than or equal to a length/width of the metal gate stack along a first direction) of the FinFET device to less than for example 10 nm or even 8 nm, it is difficult to effectively improve the gate trenches formed by a metal material filling gate-last process, and the cost remains high due to the complexity of the process. On the Other hand, a conventional polysilicon gate structure which is applied to a planar large-scale MOSFET is difficult to be applied to the FinFET in a gate-last process, since it is difficult for a device with a short channel and a short gate length to accurately control uniform distribution of the doping agent in the narrow gate, and therefore, the formed polysilicon gate meets technical challenges such as difficulty in control of the SCE, difficulty in accurate adjustment of the threshold voltage and the like.

So, it is desirable to overcome one or more of the above mentioned technical difficulties. Accordingly, there is provided a novel FinFET structure and a method of manufacturing the same so as to, for example, effectively improve the adjusting accuracy of the threshold voltage of the doped poly-semiconductor gate and/or suppress SCE at, e.g., a low cost.

Thus, the present disclosure provides a semiconductor device comprising: a plurality of fin structures extending on a substrate along a first direction; a gate stack structure extending on the substrate along a second direction and across the plurality of fin structures, wherein the gate stack structure comprises a gate conductive layer and a gate insulating layer, and the gate conductive layer is formed by a doped poly-semiconductor; trench regions in the plurality of fin structures and beneath the gate stack structure; and source/drain regions on the plurality of fin structures and at both sides of the gate stack structure along the first direction.

In an embodiment, the doped poly-semiconductor is any of poly-Si, poly-SiGe, poly-Si:C, poly-Si:H, poly-Ge, poly-SiGeC, poly-GeSn, poly-SiSn, poly-InP, poly-GaN, poly-InSb, poly-carbonized semiconductor or a combination selected therefrom.

In an embodiment, the gate insulating layer is merely beneath the gate conductive layer.

In an embodiment, the source/drain regions comprise source/drain extension regions in the plurality of fin structures and raised source/drain regions above the source/drain extension regions.

In an embodiment, a punch through stop layer exists in the middle and/or at the bottom of the plurality of fin structures.

The present disclosure further provides a method of manufacturing a semiconductor device, the method comprising: forming a plurality of fins extending along a first direction on a substrate; forming an insulating layer and a doped poly-semiconductor layer extending along a second direction on the fins; etching the doped poly-semiconductor layer and the insulating layer in turn along the second direction, to form a gate conductive layer and a gate insulating layer respectively; and forming a gate spacer and source/drain regions at both sides of the gate stack structure along the first direction.

In an embodiment, the method further comprises: before forming the gate stack structure, implementing ion implantation to form a punch through stop layer in the middle and/or at the bottom of the fins.

In an embodiment, forming a doped poly-semiconductor layer further comprises: depositing an insulating layer and a poly-semiconductor layer on the fins, and then implementing doping ion implantation in the poly-semiconductor layer; or implementing deposition in-situ and doping on the fins to form the doped poly-semiconductor layer.

In an embodiment, the doped poly-semiconductor is any of poly-Si, poly-SiGe, poly-Si:C, poly-Si:H, poly-Ge, poly-SiGeC, poly-GeSn, poly-SiSn, poly-InP, poly-GaN, poly-InSb, poly-carbonized semiconductor or a combination selected therefrom.

In an embodiment, forming source/drain regions further comprises: forming a first gate spacer at both sides of the gate stack structure; implementing lightly-doping ion implantation on the fins by taking the first gate spacer as a mask, to form source/drain extension regions; epitaxially growing raised source/drain regions on the source/drain extension regions at both sides of the first gate spacer; forming a second gate spacer at both sides of the first gate spacer; and implementing heavily-doping ion implantation on the raised source/drain regions by taking the second gate spacer as a mask.

In an embodiment, the method further comprises: after depositing the poly-semiconductor layer and before implementing doping ion implantation, implementing a planarization process on the poly-semiconductor layer; or after forming the doped poly-semiconductor layer and before etching the doped poly-semiconductor layer, implementing a planarization process on the doped poly-semiconductor layer.

According to an embodiment of the semiconductor device and the method of manufacturing the same of the present disclosure, a poly-semiconductor gate is doped in a large area and then etched to form gate lines, which can effectively improve the adjusting accuracy of the threshold voltage of the doped poly-semiconductor gate, and suppress SCE at a low cost.

### BRIEF DESCRIPTION OF THE DRAWINGS

The technical solutions of the present disclosure are illustrated in detail by referring to the accompany figures, in which:

FIGS. 1-12 are schematic views of respective steps of a method of manufacturing a FinFET according to the present disclosure; and

FIG. 13 is a perspective view of a FinFET device according to the present disclosure.

### DETAILED DESCRIPTION

The characteristics and effects of the present disclosure are illustrated in detail by referring to the accompany figures and in conjunction with the embodiments. The present disclosure discloses a 3D multi-gate FinFET and a method of manufacturing the same which effectively improves the adjusting accuracy of the threshold voltage of the poly-semiconductor gate. It should be noted that similar reference signs refer to similar structure. The terms such as “first”, “second”, “upper”, “lower” and the like are used to illustrate the respective device structures or the manufacturing procedures. Unless there is specially stated, those terms do not indicate the relationship of the device structure and manufacturing procedure in space, order or rating.

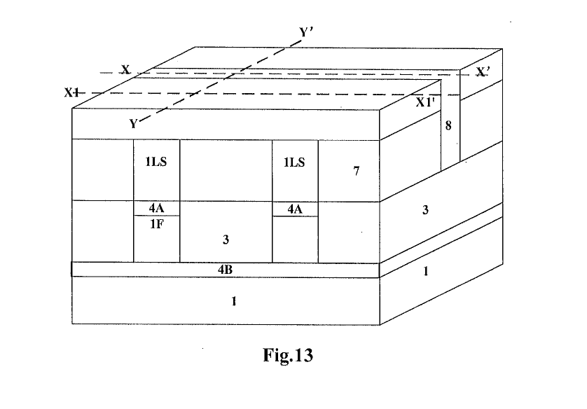

It should be noted that the upper portion in the respective figures show a sectional view of the device along the first direction in FIG. 13 (the extending direction of the fin and the extending direction of the source/drain regions, i.e. Y-Y′ axial line). The middle portions show a sectional view of device along the central line of the gate stack in a second direction (the extending direction of the gate stack perpendicular to the first direction, i.e. X-X′ axial line). The lower portions show a sectional view of the device obtained at a position parallel to the second direction and outside of the gate stack (that is a certain distance along the first direction).

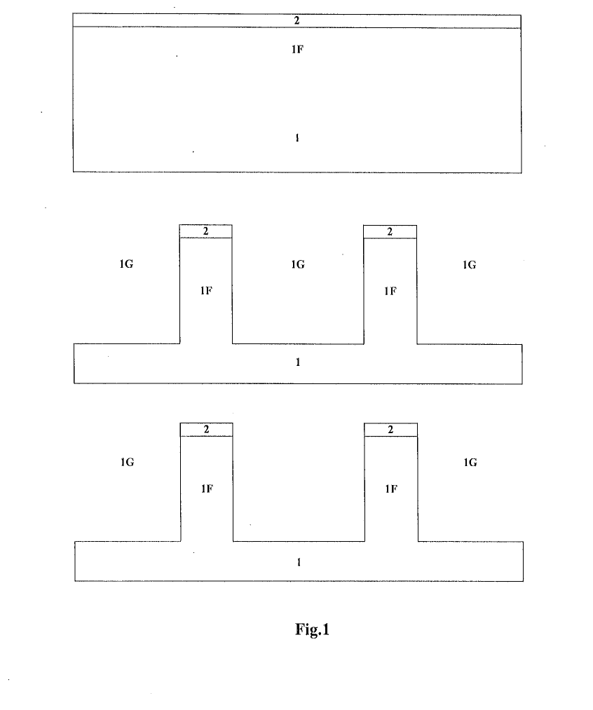

As shown in FIG. 1, a plurality of fin structures 1F and trenches 1G between the fin structures are formed on a substrate 1 along a first direction. The first direction is an extending direction of a channel region of the device (the Y-Y′ axis line in FIG. 13). The substrate 1 may be appropriately selected according to the usage of the device and may comprise one of monocrystal bulk silicon (Si), a monocrystal bulk germanium (Ge), a strained silicon (Strained Si), silicon germanium (SiGe), a semiconductor compound material such as gallium nitride (GaN), gallium arsenide (GaAs), indium phosphide (InP), indium antimonide (InSb), or a carbon-based semiconductor such as graphene, SiC, carbon nanotube, or the like. In consideration of the compatibility with a CMOS process, the substrate 1 is desirably bulk silicon. In an embodiment, a hard mask layer 2 is formed on the substrate 1, for example, a silicon nitride or silicon oxynitride layer 2 formed by a process such as LPCVD, PECVD, sputtering or the like. A photoresist is applied on the hard mask layer 2 and is exposed and developed to form a photoresist pattern (not shown). The hard mask layer 2 is etched to form a hard mask pattern by taking the photoresist pattern as a mask, and the substrate 1 is further etched by further taking the hard mask pattern 2 as a mask, so as to form a plurality of trenches 1G extending in parallel along a first direction and fins 1F composed of the remaining substrate 1 between the trenches 1G. Desirably, the etching is anisotropic etching, such as a plasma dry etching, reactive ion etching (RIE) or tetramethylammonium hydroxide (TMAH) wet etching, so that a depth-width ratio of the trench 1G is desirably larger than 5:1. A width of the fin 1F along a second direction is, for example, only 5-50 nm, and desirably ranging from 1-20 nm.

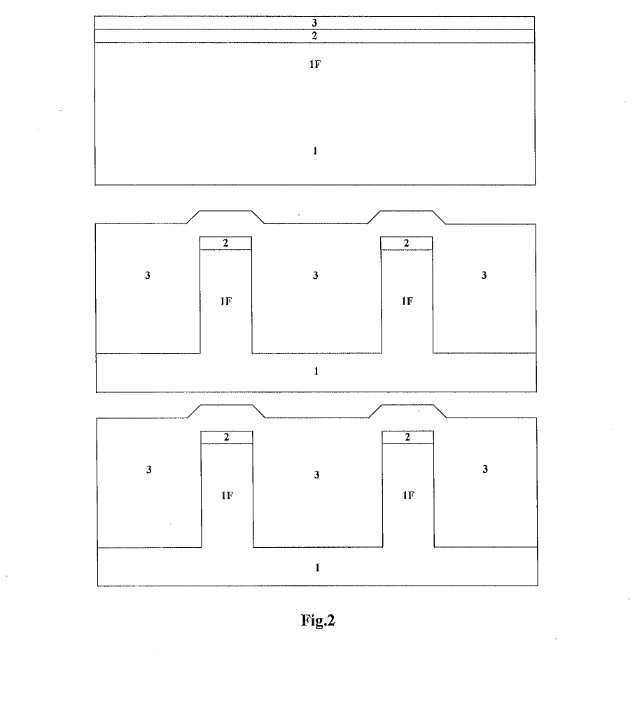

As shown in FIG. 2, an isolating dielectric layer 3 is formed between the fin structure 1F and the substrate 1. For example, an insulating isolation dielectric layer 3 is formed in the trenches 1G between the fins 1F by depositing a filling material such as silicon oxide, silicon oxynitride, silicon hydroxide, organic substrate or the like by a process such as PECVD, HDPCVD, RTO (rapid thermally oxidation), spin coating, FlowCVD and so on. As shown in FIG. 2, due to the existence of the fin structure 1F, the deposited layer 3 has protrusions on the top of the fin structure 1F. Desirably, the layer 3 is processed by a planarization process such as CMP, etch-back or the like until the hard mask layer 2 is exposed.

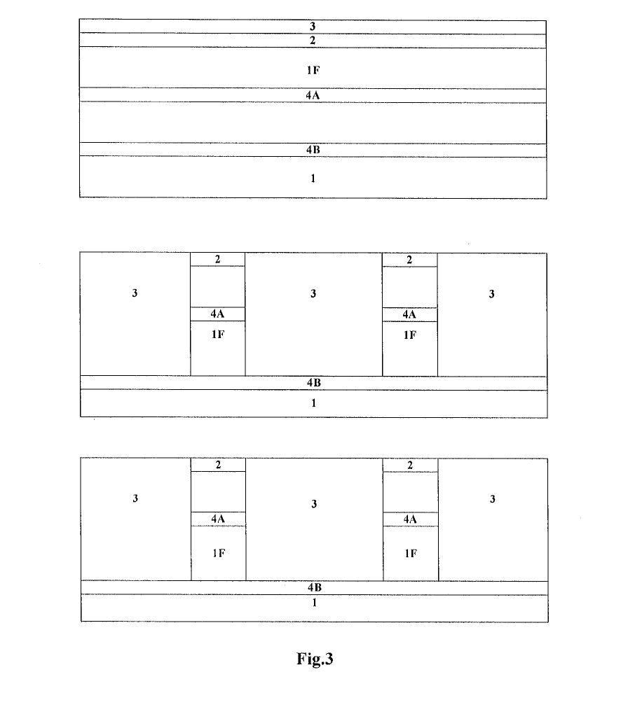

As shown in FIG. 3, a punch through stop layer (PTSL) 4 is formed in the fin 1F and/or at the bottom. After the structure shown in FIG. 2 is planarized to expose the hard mask layer 2, an ion implantation is implemented, and the ions may comprise one of N, C, F, P, Cl, As, B, In, Sb, Ga, Si, Ge or a combination selected therefrom. Subsequently, an annealing is implemented, for example, thermal processing at a temperature of about 500-1200 degrees Celsius for about 1 ms-10 min, so that the implanted element reacts with the fin 1F to form a highly doped (e.g., doped with the Si in the above mentioned materials) or insulating (e.g. doped with the silicon oxide in the above mentioned materials) punch through stop layer 4. In one embodiment of the present disclosure, the doping energy and doping dosage are controlled to form a channel punch through stop layer 4A only in the fin 1F, as shown in FIG. 3, so as to suppress the leakage from the channel region through the side surface of the STI region. However, in another embodiment of the present disclosure, the doping energy and doping dosage are controlled so that the punch through stop layer 4 is further distributed at an interface between the bottom of the fin 1F and the substrate 1 as a STI punch through stop layer 4B, so as to effectively isolate a leakage current between the channel region and source/drain regions in the fin 1F as well as the active region of the adjacent fins. The material for the layer 4B may be identical to that of the layer 4A, and may also contain a different component from the above mentioned elements (but at least containing oxygen). The layer 4B and the layer 4A may be synchronously formed by one batch of implantation (the implantation depths for different elements are different from each other), and may also be formed by two implantation steps with different depths and dosages, for example, the layer 4B is formed by an implantation with a deep depth and then the layer 4A is formed by an implantation with a shallow depth, vice versa. In addition, except for the highly doped punch through stop layer as mentioned above, an amount of oxygen (O) may be implanted to form a silicon oxide based insulating layer as the punch through stop layer (the silicon oxide layer may be further doped with the above mentioned impurity). It should be noted that the distance from the channel punch through stop layer 4A to the top (or bottom) of the fin 1F may be arbitrarily set, and in one embodiment of the present disclosure, it is desirably set to be ⅓-½ of the height of the fin 1F itself. For example, the thickness of the STI punch through stop layer 4B and the channel punch through stop layer 4A may range from 5-30 nm. The width of the layer 4B (along the first and/or second direction) may be set according to the width of the active region of the whole device and the width of the layer 4A is identical to that of the fin 1F, i.e. the width of the layer 4B is obviously larger than that of the layer 4A.

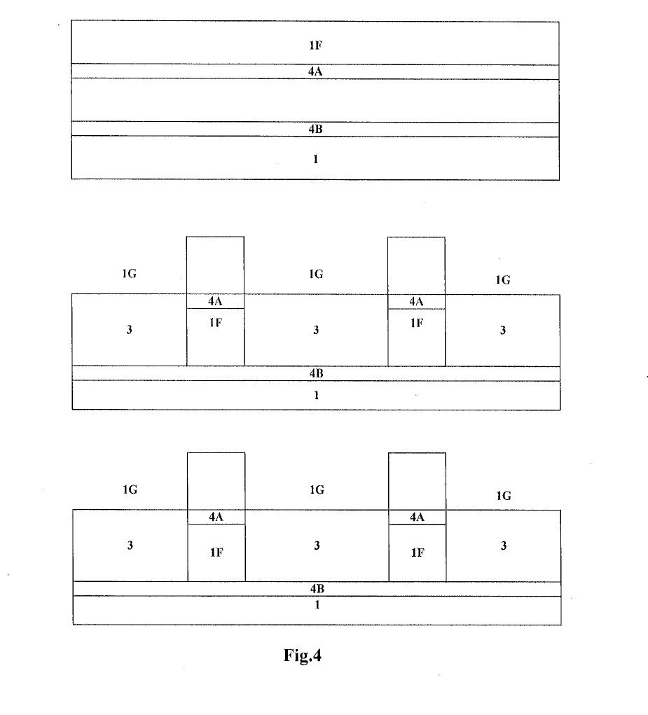

As shown in FIG. 4, the isolating layer 3 is selectively etched to form a trench 1G again and to expose one portion of the fin 1F. The isolating layer 3 is etched by selecting an anisotropic etching such as plasma dry etching or RIE and by utilizing the photoresist pattern or other hard mask pattern, so that the remaining isolating layer 3 forms a shallow trench isolation (STI) region 3. Desirably, the depth of the trench 1G, i.e. the distance from the top of the STI region 3 to the top of the fin 1F, is larger than or equal to the distance from the top of the punch through stop layer 4A to the top of the fin 1F, so as to completely suppress the punching through between the channel regions. Subsequently, the hard mask 2 is removed by a wet etching.

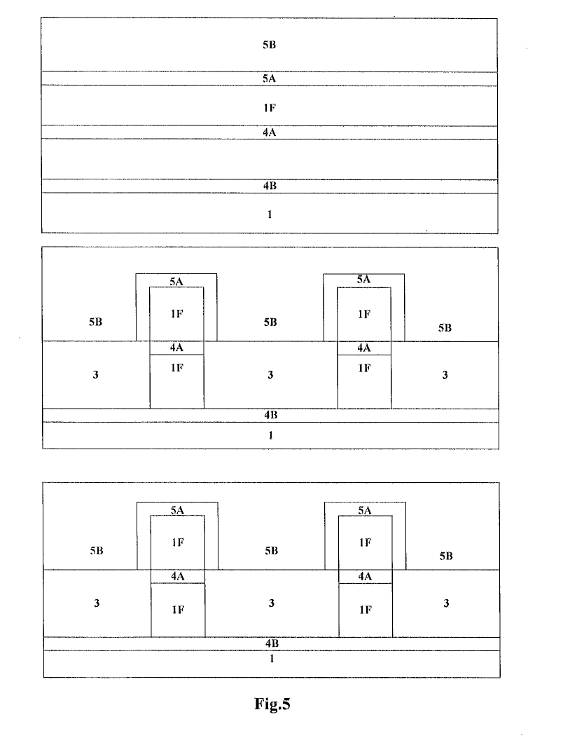

As shown in FIG. 5, an insulating layer 5A and a poly-semiconductor material layer 5B are formed on the whole substrate, i.e., on the fin 1F and the STI 3. For example, the insulating layer 5A and the poly-semiconductor layer 5B are formed on the whole device structure by a conventional process such as PECVD, HDPCVD, MOCVD, MBE, ALD, evaporating, sputtering or the like. For example, the insulating layer 5A may be of a material such as oxide, nitride, oxynitride or other high-k material, for example, silicon oxide, silicon nitride, or silicon oxynitride. The high-k material includes and is not limited to a Hf-based material (in which the content of the oxygen atom x may be reasonably adjusted according to the ratio of the metal compositions and the chemical valence, for example, x may be 1-6 and is not to an integer number) selected from: HfO₂, HfSiOₓ, HfSiON, HfAIOₓ, HfTaOₓ, HfLaOₓ, HfAISiOₓ or HfLaSiOₓ, or a rare earth element-based high-k dielectric material selected from: ZrO₂, La₂O₃, LaAlO₃, TiO₂ or Y₂O₃, or Al₂O₃, or a composite layer of two or more of the above mentioned materials. The poly-semiconductor layer 5B may be of a material such as poly-Si, poly-SiGe, poly-Si:C, poly-Si:H, poly-Ge, poly-SiGeC, poly-GeSn, poly-SiSn, poly-InP, poly-GaN, poly-InSb, poly-carbonized semiconductor or the like. Process parameters may be selected, for example to improve a deposition temperature (850-1300 degrees Celsius, for example) so that the poly-semiconductor layer of the above mentioned materials is formed in one step; or an amorphous or microcrystalline semiconductor layer of the above mentioned materials is firstly formed at a lower temperature (600-800 degrees Celsius, for example), and then crystal particles in the semiconductor layer are recombined by a remedy process such as laser annealing, RTA annealing or the like to form the poly-semiconductor layer.

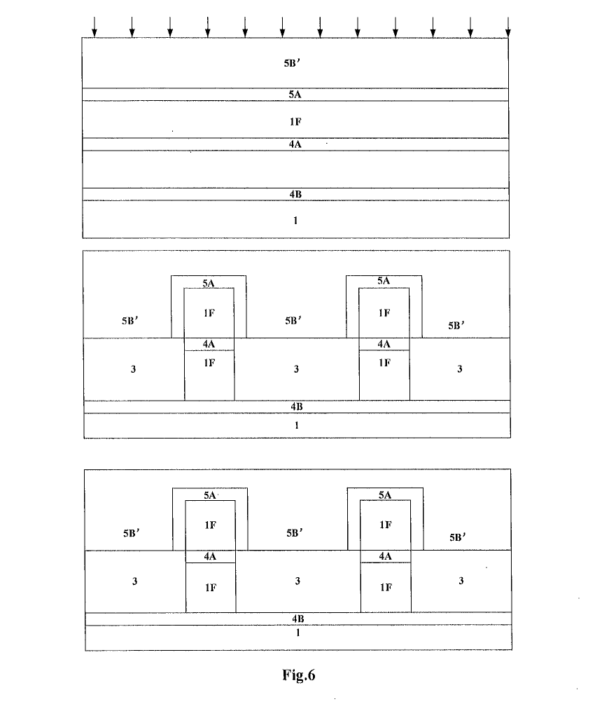

As shown in FIG. 6, the poly-semiconductor layer 5B is doped to form a doped poly-semiconductor layer 5B′. In an embodiment, different doping agents may be implanted into the poly-semiconductor gate by ion implantation according to different types of the device, to adjust a desired threshold voltage. For example, B, In, Mg, Be, Al, Ga, Sn or the like is implanted for PFinFET, and P, As, N, Sb, Bi, S, Se, Te or the like is implanted for nFinFET. Then, the whole device is desirably processed by annealing (for example, at an annealing temperature of 600-800 degrees Celsius for an annealing time of 1 s-3 min), to activate impurities and facilitate uniform distribution of the impurities in the whole poly-semiconductor layer 5B, thereby forming the doped poly-semiconductor layer 5B′. In this process, compared with the process of firstly forming gate lines and then implementing doping, the device and method of manufacturing the same of the present disclosure prevent a large local jump in the doping concentration of the small-sized gate lines due to non-uniform distribution of the directions of the ion implantation or due to accidental fluctuation in the plasma ignition jet system by implementing implantation in a large area and then implementing activation and annealing, and also enhance the uniformity of the distribution of the doping agent in the doped layer 5B′ by diffusion in a large area and at a long distance, which facilitates accurate control of the threshold voltage of the device, thereby obtaining stable and uniform electrical characteristics in different regions of the substrate.

It should be noted that although FIGS. 5 and 6 show an embodiment in which deposition is firstly implemented and then doping implantation is implemented, the processes in FIGS. 5 and 6 may be combined as implementing deposition in-situ by intermittently or alternatively introducing raw gases of the doping agent (for example, fluoride or hydride or the like of the above mentioned doping agent) in a deposition chamber, and then implementing activation and annealing at the same time, thereby facilitating uniform distribution of the doping agent.

In the above deposition process, due to the influence from the fins on the substrate, the top of the poly-semiconductor layer has an uneven shape (not shown), which influences the accuracy of the ion implantation. For example, as the top has a protrusion shape, the top absorbs more impurities locally, while the root region of the protrusion may have fewer impurities than the adjacent regions. In this case, when the device is formed subsequently, a periodic variation may occur in the distribution of the impurities. Therefore, according to an embodiment of the present disclosure, after the poly-semiconductor layer is deposited and before doping ion implantation is implemented, the following step is further applied: implementing a planarization process on the poly-semiconductor layer; or after the doped poly-semiconductor layer is formed and before the doped poly-semiconductor layer is etched, the following step is further applied: implementing a planarization process on the doped poly-semiconductor layer.

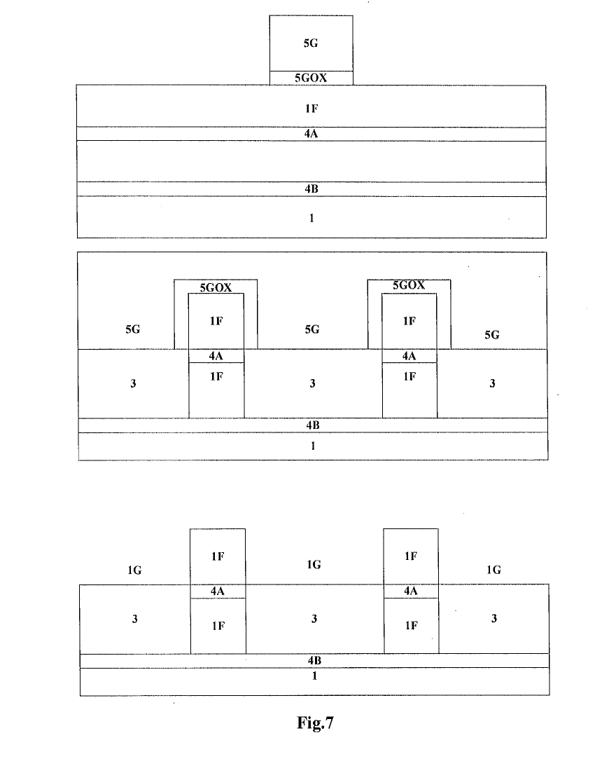

As shown in FIG. 7, a patterning process is implemented on the doped semiconductor layer 5B′ and the insulating layer 5A, to form a gate stack 5 extending along the second direction. For example, a photoresist (not shown) is applied on the whole device, and is subjected to exposure and development by using a mask or a reticle having lines extending along the second direction (which is desirably perpendicular to the direction in which the fins 1F extend) to form a plurality of photoresist patterns extending along the second direction. Then, the doped poly-semiconductor layer 5B′ and the insulating layer 5A are etched in turn by taking the photoresist patterns as a mask, until the top of the fin structures 1F and the top of the STI 3 are exposed. The etching process is desirably an anisotropic etching, for example, plasma dry etching, RIE or the like. The etching gas may be a fluorocarbon-based etching gas for a Si-based material (for example, poly-Si, silicon oxide, silicon nitride or the like), or may also be a halogen etching gas (for example, Cl₂, Br₂, HBr, HCl or the like) for a non-Si-based material (for example, poly-SiGe, poly-Ge, or other high-k material). The remaining doped poly-semiconductor layer 5B′ forms a gate conductive layer 5G of a poly-material, while the remaining insulating layer 5A forms a gate insulating layer 5GOX. As described above, as doping is implemented in a large area and activation and annealing are implemented, a uniform distribution of the doping agent is achieved in the gate 5G, thereby enabling accurate control of the threshold voltage of the device. As shown in the top and middle of FIG. 7, the gate stack 5 (5G/5GOX) is merely distributed in a width range along the X-X′ axial line rather than positions along the X1-X1′ axial line away from the range.

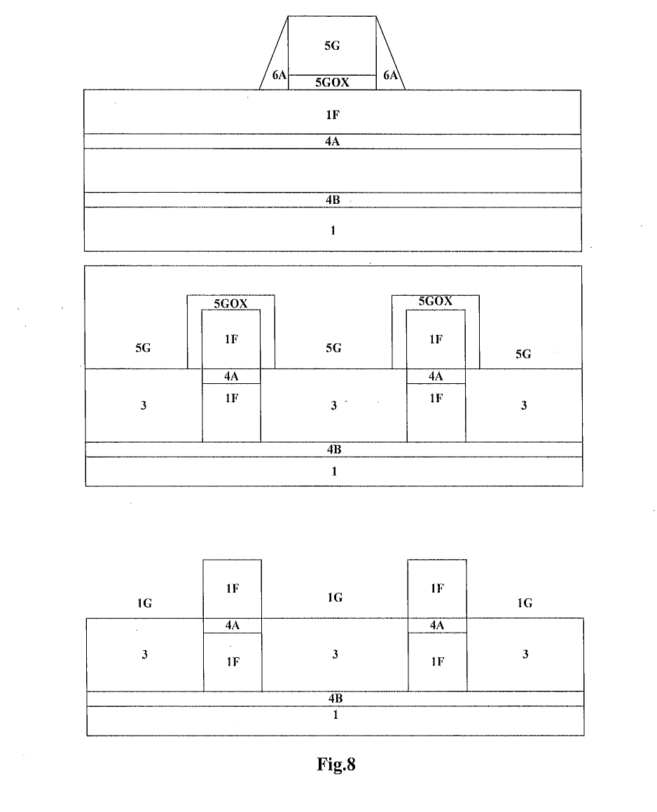

As shown in FIG. 8, a first gate spacer 6A is formed at both sides of the gate stack 5 along the first direction. An insulating material layer 6 is formed on the whole device by a process such as LPCVD, PECVD, HDPCVD, UHVCVD, MOCVD, MBE, ALD, evaporation, (magnetron) sputtering or the like. The insulating material layer 6 is made of a material such as silicon nitride, silicon oxynitride, silicon oxide, C-containing silicon oxide, amorphous carbon, diamond-like amorphous carbon (DLC) or a combination selected therefrom. In an embodiment of the present disclosure, the material is desirably silicon nitride. Then, the insulating material layer 6 is etched by an anisotropic etching process, to leave the first gate spacer 6A only at both sides of the gate stack structure 5 along the first direction. It should be noted that although the first gate spacer 6A is in a triangular shape as shown in FIG. 6, in another embodiment of the present disclosure, the spacer 6A is in an L shape. That is to say, the spacer 6A has a first horizontal portion and a second vertical portion to keep good conformation with the gate stack 5, thereby achieving a reduced thickness of the gate spacer 6A, a further reduced size of the device, and improved uniformity of the device. In an embodiment of the present disclosure, the layer 6A may have a thickness of merely 1-5 nm for example, and desirably, 2-4 nm, and most desirably, 3 nm.

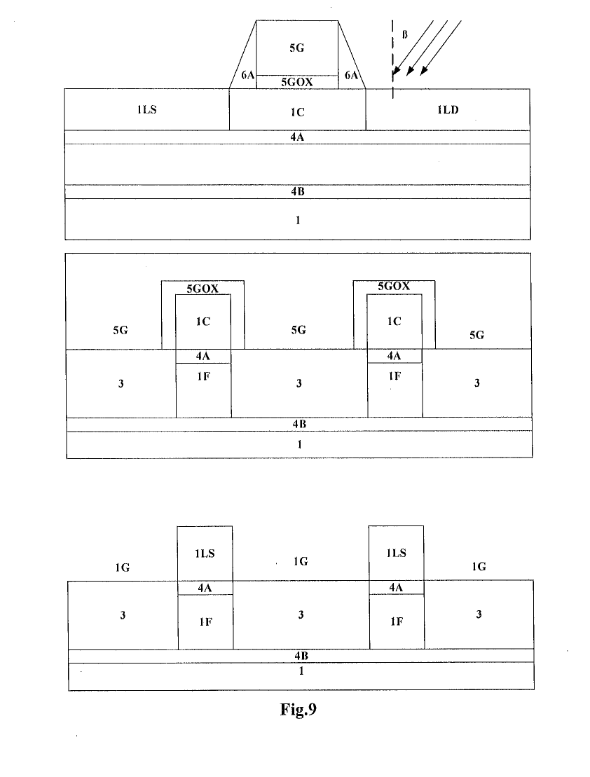

Then, as shown in FIG. 9, lightly-doping ion implantation is implemented on the substrate including the device by taking the first gate spacer 6A as a mask, to form LDD or SDE structures 1LS/1LD in fin 1F at both sides of the gate stack 5 and the gate spacer 6A along the first direction, and the fin 1F between the LDD or SDE structures 1LS/1LD serve as a trench region 1C, A vertical tilt angle 13 (an acute angle between the implantation direction and the vertical direction) may be 0-45°±0.5° for example. A symmetric LDD/SDE structure may be formed at both sides of the gate stack structure 5 along the first direction by rotating the substrate 1 or rotating a nozzle in an ion implementation chamber 180 degrees by taking the vertical direction as an axial line. In addition, according to an embodiment of the present disclosure, the vertical tilt angle β may be adjusted by changing a longitudinal junction depth (along the vertical direction) of the LDD/SDE structure, thereby controlling the characteristics of the bottom interface between the source/drain regions and the fin 1F.

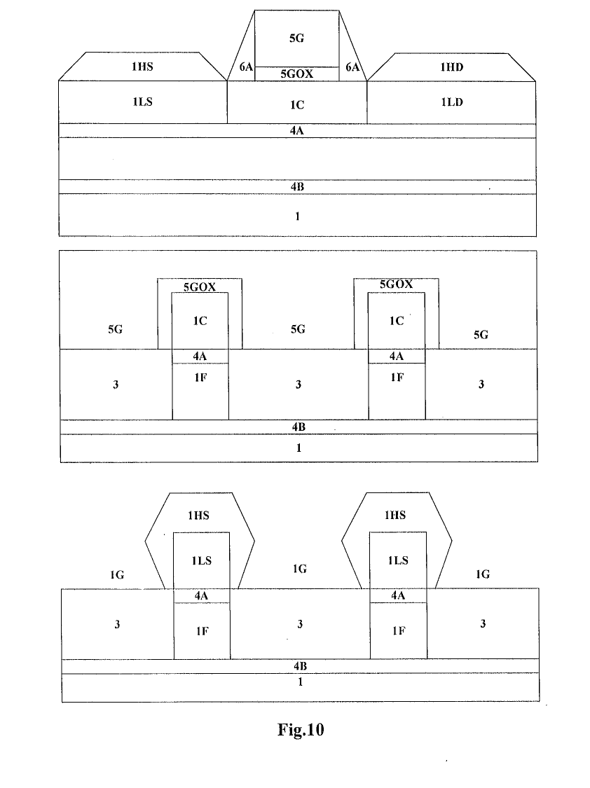

As shown in FIG. 10, raised source/drain regions 1HS/1HD are grown epitaxially on LDD source/drain regions 1LS/1LD at both sides of the gate spacer 6A along the first direction. For example, the raised source/drain regions 1HS/1HD are grown epitaxially at both sides of the gate stack structure 5/gate spacer 6A along the first direction by a process such as PECVD, MOCVD, MBE, ALD, thermal decomposition, evaporation, sputtering or the like. The raised source/drain regions 1HS/1HD may be of a different material from the substrate 1 and the fins 1F, for example, SiGe, Si:C, Si:H, SiSn, GeSn, SiGe:C or a combination selected therefrom with higher stress. In this process, doping may be implemented in situ or by ion implantation to adjust the doping type and/or concentration of the source/drain regions. As shown in the lower portion of FIG. 10, as epitaxial growth has different growth rates in various facets, the finally formed raised source/drain regions tend to have a cross section of rhombus or diamond shape.

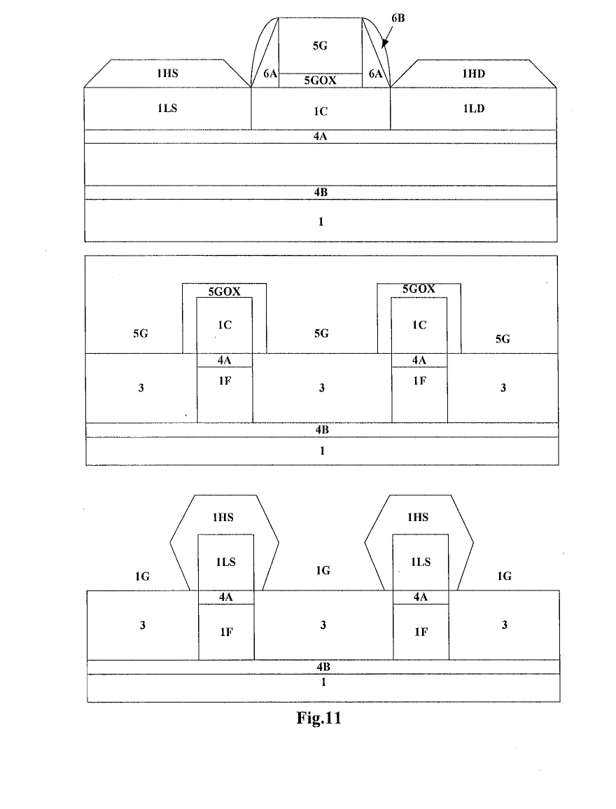

As shown in FIG. 11, a second gate spacer 6B is further formed on the first gate spacer 6A, and may have a similar material and process as that of the first gate spacer. Then, second ion implantation is implemented by taking the second gate spacer 6B as a mask, to implement heavily doping in the source/drain regions (at a shallow longitudinal junction depth), so that the raised source/drain regions 1HS/1HD have a higher doping concentration than source/drain regions and lightly-doped source/drain regions 1LD/1LS. Then, annealing is implemented to activate the doping impurities. In this case, the annealing further mitigates damages to the top of the fin structures due to LDD/SDE implantation and reduces defects in the epitaxial layer, which are beneficial to improve the reliability of the device by a simplified process.

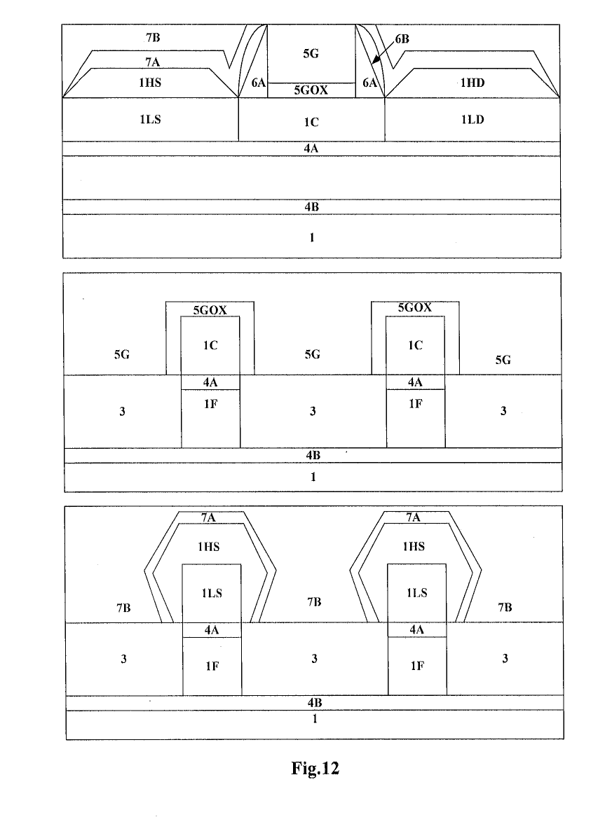

As shown in FIG. 12, a CESL 7A and an ILD 7B are formed on the whole device. Desirably, a CESL 7A of silicon nitride is firstly formed on the device by a process such as PECVD, HDPCVD, sputtering or the like (omissible). Then, an ILD 7B of silicon oxide with a low-k material is formed by a process such as spin coating, spray coating, screen printing, CVD, PVD or the like. The low-k material includes and is not limited to an organic low-k material (for example, an organic polymer containing aryl group or polycyclic group), an inorganic low-k material (for example, an amorphous carbon nitride film, a polycrystalline boron nitride film, silicon fluoride glass, BSG, PSG, or BPSG), a porous low-k material (for example, a porous silsesquioxane (SSQ) based low-k material, porous silicon dioxide, porous SiOCH, C-doped silicon dioxide, porous F-doped amorphous carbon, porous diamond, or porous organic polymer).

Subsequently, an interconnection of the device is accomplished by a conventional process. For example, the ILD layer 7B and the CESL 7A are etched in turn until the raised source/drain region 1HS/1HD is exposed to form a contact via. Desirably, the etching method may be an anisotropic dry etching, such as plasma etching or RIE. Desirably, a metal silicide (not shown) is formed on the source/drain region exposed by the contact via to decrease the contact resistance. For example, a metal layer (not shown) is formed in the contact via by evaporation, sputtering, MOCVD, MBE, ALD or the like, and the material for the metal layer may be a metal such as Ni, Pt, Co, Ti, W or the like, or an alloy of one or more of these metals. An anneal is implemented at a temperature of about 250-1000 degrees Celsius for about 1 ms-10 min so that the metal or metal alloy reacts with the Si element contained in the source/drain region to form a metal silicide and to decrease the contact resistance. Subsequently, a contact metal layer is filled into the contact via, for example, by a process such as MOCVD, MBE, ALD, evaporation, sputtering or the like to form the contact metal layer. Desirably, the material for the contact metal layer may be a material with a better extensibility, a higher filling rate and a lower cost, e.g. a metal such as W, Ti, Pt, Ta, Mo, Cu, Al, Ag, Au or the like, an alloy of two or more of these metals or a nitrides of one or more of these metals. Subsequently, a process such as CMP or etching back is used to planarize the contact metal layer until the CESL 7A is exposed.

A finally formed device has a structure as shown in FIG. 12, which comprises a plurality of fin structures 1F extending on a substrate 1 along a first direction with a plurality of STIs 3 existing among the a plurality of fin structures 1F; a gate stack structure comprising a gate conductive layer 5G and a gate insulating layer 5GOX across each fin structure and extending along a second direction, with fin structures beneath the gate stack structure 5 serving as trench regions 1C; and source/drain regions formed on the fin structures at both sides of the gate stack along the first direction; wherein the gate conductive layer 5G is formed by a doped poly-semiconductor, and the gate insulating layer 5GOX is merely distributed beneath the gate conductive layer 5G. Other structures, materials and parameters and the like of the device have been described in the manufacturing process with reference to FIGS. 1-12, and will not be described here again.

According to an embodiment of the semiconductor device and the method of manufacturing the same of the present disclosure, a poly-semiconductor gate is doped in a large area and then etched to form gate lines, which can effectively improve the adjusting accuracy of the threshold voltage of the doped poly-semiconductor gate, and suppress SCE at a low cost.

The present disclosure has been described above with reference to one or more example embodiments. It should be understood that various suitable alternations and equivalents can be made to the device structure and/or process by one skilled person in the art without departing from the spirit and scope of the present disclosure. Moreover, the teachings of the present disclosure may make various modifications which may be adapted for particular situations or materials without departing from the spirit and scope of the present disclosure. Therefore, the present disclosure is not limited to the above particular embodiments as desired implementations of the present disclosure. The device structure and the manufacture method thereof as disclosed will include all of embodiments falling within the scope of the present disclosure.

What is claimed is:

1. A semiconductor device, comprising:
a plurality of fin structures extending along a first direction on a substrate;
a gate stack structure extending along a second direction on the substrate and across the plurality of fin structures, wherein the gate stack structure comprises a gate conductive layer and a gate insulating layer, and the gate conductive layer is formed by a doped poly-semiconductor;
trench regions in the plurality of fin structures and beneath the gate stack structure; and
source/drain regions on the plurality of fin structures and at both sides of the gate stack structure along the first direction.

2. The semiconductor device according to claim 1, wherein the doped poly-semiconductor comprises a material selected from: poly-Si, poly-SiGe, poly-Si:C, poly-Si:H, poly-Ge, poly-SiGeC, poly-GeSn, poly-SiSn, poly-InP, poly-GaN, poly-InSb, poly-carbonized semiconductor or a combination selected therefrom.

3. The semiconductor device according to claim 1, wherein the gate insulating layer is merely beneath the gate conductive layer.

4. The semiconductor device according to claim 1, wherein the source/drain regions comprises source/drain extension regions in the plurality of fin structures and raised source/drain regions above the source/drain extension regions.

5. The semiconductor device according to claim 1, wherein a punch through stop layer is in the middle and/or at the bottom of the plurality of fin structures.

6. A method of manufacturing a semiconductor device, the method comprising:
forming a plurality of fins extending along a first direction on a substrate;
forming an insulating layer and a doped poly-semiconductor layer extending along a second direction on the fins;
etching the doped poly-semiconductor layer and the insulating layer in turn along the second direction, to form a gate conductive layer and a gate insulating layer, respectively; and
forming a gate spacer and source/drain regions at both sides of the gate stack structure along the first direction.

7. The method according to claim 6, further comprising, before forming the gate stack structure, implementing an ion implantation to form a punch through stop layer in the middle and/or at the bottom of the fins.

8. The method according to claim 6, wherein forming the doped poly-semiconductor layer further comprises:
depositing an insulating layer and a poly-semiconductor layer on the fins, and then implementing a doped ion implantation in the poly-semiconductor layer; or
implementing an in-situ deposition and doping on the fins to form the doped poly-semiconductor layer.

9. The method according to claim 8, further comprising, after depositing the poly-semiconductor layer and before implementing the doped ion implantation, implementing a planarization process on the poly-semiconductor layer; or after forming the doped poly-semiconductor layer and before etching the doped poly-semiconductor layer, implementing a planarization process on the doped poly-semiconductor layer.

10. The method according to claim 6, wherein the doped poly-semiconductor comprises a material selected from: poly-Si, poly-SiGe, poly-Si:C, poly-Si:H, poly-Ge, poly-SiGeC, poly-GeSn, poly-SiSn, poly-InP, poly-GaN, poly-InSb, poly-carbonized semiconductor or any combination selected therefrom.

11. The method according to claim 6, wherein forming source/drain regions further comprises:
forming a first gate spacer at both sides of the gate stack structure;
implementing lightly-doping ion implantation on the fins by taking the first gate spacer as a mask, to form source/drain extension regions;
epitaxially growing raised source/drain regions on the source/drain extension regions at both sides of the first gate spacer;
forming a second gate spacer at both sides of the first gate spacer; and
implementing heavily-doping ion implantation on the raised source/drain regions by taking the second gate spacer as a mask.
